(19) United States
(12) Patent Application Publication
(10) Pub. No.: US 2025/0287676 A1
(43) Pub. Date: Sep. 11, 2025

(54) SEMICONDUCTOR DEVICE, METHOD FOR MANUFACTURING SEMICONDUCTOR DEVICE, INVERTER CIRCUIT, DRIVING DEVICE, VEHICLE, AND ELEVATOR

(71) Applicant: KABUSHIKI KAISHA TOSHIBA, Tokyo (JP)

(72) Inventor: Tatsuo SHIMIZU, Shinagawa Tokyo (JP)

(73) Assignee: KABUSHIKI KAISHA TOSHIBA, Tokyo (JP)

(21) Appl. No.: 19/068,059

(22) Filed: Mar. 3, 2025

(30) Foreign Application Priority Data
Mar. 8, 2024 (JP) 2024-035833

(51) Int. Cl. H10D 64/68; B60R 16/02; B61C 3/00; B66B 11/04; H02P 27/06; H10D 30/01; H10D 30/66; H10D 62/832; H10D 64/01

(52) U.S. Cl. CPC H10D 64/68; H10D 30/0291; H10D 30/66; H10D 62/8325; H10D 64/01; B60R 16/02; B61C 3/00; B66B 11/043; H02P 27/06

(57) ABSTRACT

A semiconductor device of an embodiment includes a silicon carbide layer, a gate electrode, a silicon oxide layer between the silicon carbide layer and the gate electrode, and containing carbon (C), nitrogen (N), and hydrogen (H), and a region between the silicon carbide layer and the silicon oxide layer and having a nitrogen concentration equal to or more than 1×10²¹ cm⁻³, in which a nitrogen concentration distribution has a peak in the region, a first concentration of nitrogen, a second concentration of carbon, and a third concentration of hydrogen at a first position 10 nm away from the peak toward the silicon oxide layer are equal to or more than 1×10¹⁸ cm⁻³, the second concentration is 80% or more and 120% or less of the first concentration, and the third concentration is 80% or more and 120% or less of the first concentration.

### CROSS-REFERENCE TO RELATED APPLICATION

This application is based upon and claims the benefit of priority from Japanese Patent Application No. 2024-035833, filed on Mar. 8, 2024, the entire contents of which are incorporated herein by reference.

### FIELD

Embodiments described herein relate generally to a semiconductor device, a method for manufacturing a semiconductor device, an inverter circuit, a driving device, a vehicle, and an elevator.

### BACKGROUND

Examples of a material for next generation semiconductor devices include silicon carbide (SiC). As compared with silicon (Si), silicon carbide has superior physical properties that a band gap is about three times of that of Si, a breakdown field strength is about ten times of that of Si, and a thermal conductivity is about three times of that of Si. These characteristics are used to achieve a semiconductor device capable of operating with a low loss at high temperature.

For example, when a metal oxide semiconductor field effect transistor (MOSFET) is formed using silicon carbide, there is a problem that carrier mobility decreases or a threshold voltage fluctuates. One factor that causes the decrease in the carrier mobility and the fluctuation in the threshold voltage is considered to be a harmful defect present in a gate insulating layer.

### BRIEF DESCRIPTION OF THE DRAWINGS

FIG. 1 is a schematic cross-sectional view of a semiconductor device of a first embodiment;

FIG. 2 is a view illustrating a crystal structure of a SiC semiconductor;

FIG. 3 is a graph illustrating element concentration distributions of the semiconductor device of the first embodiment;

FIGS. 4A and 4B are schematic views illustrating bonding states of a nitrogen atom in the semiconductor device of the first embodiment;

FIG. 5 is an explanatory view of a gate insulating layer of the semiconductor device of the first embodiment;

FIG. 6 is a flowchart of a process of a method for manufacturing the semiconductor device of the first embodiment;

FIG. 7 is an explanatory view of a function and an effect of the semiconductor device of the first embodiment;

FIG. 8 is an explanatory view of the function and the effect of the semiconductor device of the first embodiment;

FIG. 9 is an explanatory view of the function and the effect of the semiconductor device of the first embodiment;

FIG. 10 is an explanatory view of the function and the effect of the semiconductor device of the first embodiment;

FIG. 11 is a schematic cross-sectional view of a semiconductor device of a second embodiment;

FIG. 12 is a graph illustrating element concentration distributions of the semiconductor device of the second embodiment;

FIG. 13 is a schematic view of a driving device of a third embodiment;

FIG. 14 is a schematic view of a vehicle of a fourth embodiment;

FIG. 15 is a schematic view of a vehicle of a fifth embodiment; and

FIG. 16 is a schematic view of an elevator of a sixth embodiment.

### DETAILED DESCRIPTION

A semiconductor device of an embodiment includes a silicon carbide layer, a gate electrode, a silicon oxide layer provided between the silicon carbide layer and the gate electrode, and containing carbon (C), nitrogen (N), and hydrogen (H), and a region provided between the silicon carbide layer and the silicon oxide layer and having a nitrogen concentration equal to or more than 1×10²¹ cm⁻³, in which a nitrogen concentration distribution in the silicon carbide layer, the silicon oxide layer, and the region has a peak in the region, a first concentration of nitrogen at a first position 10 nm away from the peak toward the silicon oxide layer is equal to or more than 1×10¹⁸ cm⁻³, a second concentration of carbon at the first position is equal to or more than 1×10¹⁸ cm⁻³, a third concentration of hydrogen at the first position is equal to or more than 1×10¹⁸ cm⁻³, the second concentration is 80% or more and 120% or less of the first concentration, and the third concentration is 80% or more and 120% or less of the first concentration.

Hereinafter, embodiments of the present disclosure will be described with reference to the drawings. In the following description, the same or equivalent members and the like will be denoted by the same reference numerals, and members that have been once described will not be described as appropriate.

In the following description, notations n⁺, n, n⁻, p⁺, p, and p⁻ indicate relative levels of impurity concentration in each conductivity type. That is, n⁺ indicates an n-type impurity concentration higher than that of n, and n⁻ indicates an n-type impurity concentration lower than that of n. In addition, p⁺ indicates a p-type impurity concentration higher than that of p, and p⁻ indicates a p-type impurity concentration lower than that of p. In some cases, an n⁺-type and an n⁻-type are simply referred to as an n-type, and a p⁺-type and a p⁻-type are simply referred to as a p-type. Unless otherwise specified, the impurity concentration of each region is represented by, for example, a value of an impurity concentration at the center of each region.

The impurity concentration can be measured by secondary ion mass spectrometry (SIMS), for example. In addition, a relative level of the impurity concentration can also be determined based on a level of a carrier concentration obtained by, for example, scanning capacitance microscopy (SCM). In addition, a distance such as a width and a depth of an impurity region can be obtained by SIMS, for example. In addition, a distance such as a width and a depth of an impurity region can be obtained from an SCM image, for example.

A depth of a trench, a thickness of an insulating layer, and the like can be measured on an image of SIMS or a transmission electron microscope (TEM), for example.

Bonding states of silicon atoms, carbon atoms, nitrogen atoms, oxygen atoms, or hydrogen atoms in the silicon carbide layer or the gate insulating layer can be identified by using, for example, X-ray photoelectron spectroscopy (XPS method) or Fourier transform infrared spectroscopy (FT-IR method). In addition, concentrations of various bonding states and the magnitude relationship of the concentrations can be determined by using, for example, X-ray photoelectron spectroscopy or Fourier transform infrared spectroscopy.

### First Embodiment

A semiconductor device of a first embodiment includes a silicon carbide layer, a gate electrode, a silicon oxide layer provided between the silicon carbide layer and the gate electrode and containing carbon (C), nitrogen (N), and hydrogen (H), and a region provided between the silicon carbide layer and the silicon oxide layer and having a nitrogen concentration equal to or more than 1×10²¹ cm⁻³. A nitrogen concentration distribution in the silicon carbide layer, the silicon oxide layer, and the region has a peak in the region, a first concentration of nitrogen at a first position 10 nm away from the peak toward the silicon oxide layer is equal to or more than 1×10¹⁸ cm⁻³, a second concentration of carbon at the first position is equal to or more than 1×10¹⁸ cm⁻³, and a third concentration of hydrogen at the first position is equal to or more than 1×10¹⁸ cm⁻³. The second concentration is 80% or more and 120% or less of the first concentration, and the third concentration is 80% or more and 120% or less of the first concentration.

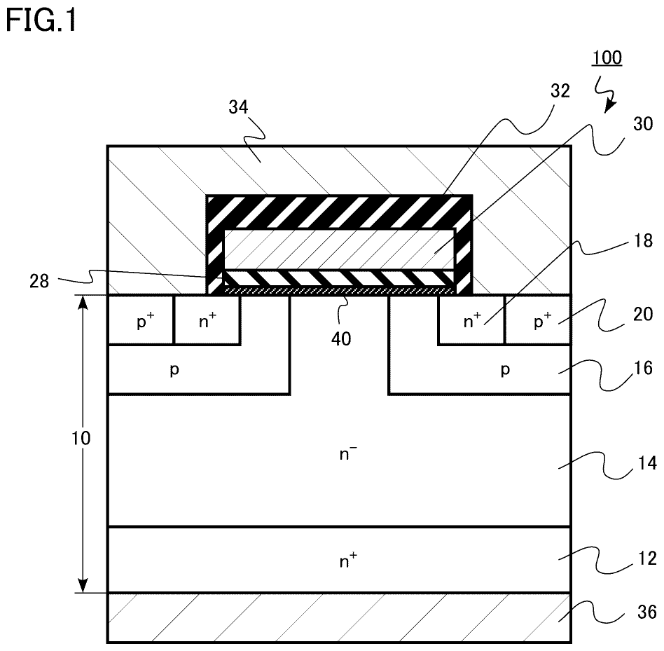

FIG. 1 is a schematic cross-sectional view of the semiconductor device of the first embodiment. The semiconductor device is a MOSFET 100. The MOSFET 100 is a double implantation MOSFET (DIMOSFET) in which a p-well and a source region are formed by ion implantation. In addition, the MOSFET 100 is an n-channel MOSFET using electrons as carriers.

The MOSFET 100 includes a silicon carbide layer 10, a gate insulating layer 28 (silicon oxide layer), a gate electrode 30, an interlayer insulating film 32, a source electrode 34, a drain electrode 36, and an interface termination region 40 (region).

The silicon carbide layer 10 includes a drain region 12, a drift region 14, a p-well region 16, a source region 18, and a p-well contact region 20.

The silicon carbide layer 10 is a single crystal of, for example, 4H—SiC. The silicon carbide layer 10 is disposed between the source electrode 34 and the drain electrode 36.

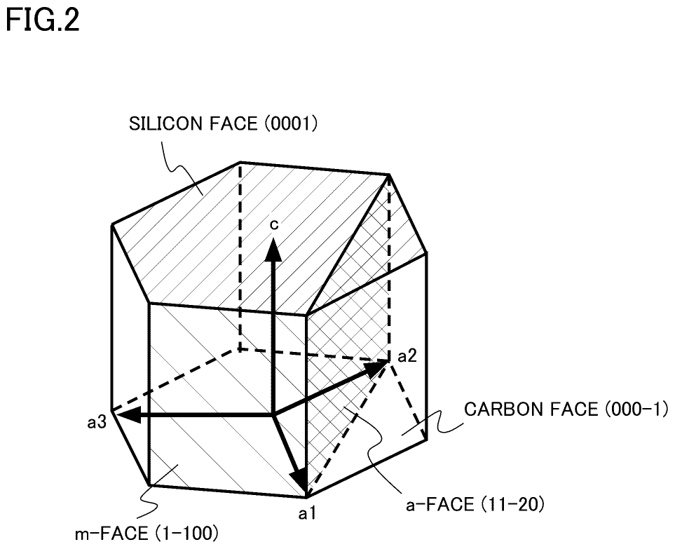

FIG. 2 is a view illustrating a crystal structure of a SiC semiconductor. A typical crystal structure of the SiC semiconductor is a hexagonal crystal system such as 4H—SiC. One of faces (bases of a hexagonal prism) whose normal line is a c-axis along the axial direction of the hexagonal prism is a (0001) face. A face equivalent to the (0001) face is referred to as a silicon face (Si face) and denoted as a {0001} face. Silicon atoms (Si) are arranged on the outermost surface of the silicon face.

The other of the faces (bases of the hexagonal prism) whose normal line is the c-axis along the axial direction of the hexagonal prism is a (000-1) face. A face equivalent to the (000-1) face is referred to as a carbon face (C face) and denoted as a {000-1} face. Carbon atoms (C) are arranged on the outermost surface of the carbon face.

On the other hand, a side face (prism face) of the hexagonal prism is an m-face which is a face equivalent to a (1-100) face, that is, a {1-100} face. In addition, a face passing through a pair of ridgelines not adjacent to each other is an a-face which is a face equivalent to a (11-20) face, that is, a {11-20} face. Both the silicon atoms (Si) and the carbon atoms (C) are arranged on the outermost surfaces of the m-face and the a-face.

Hereinafter, a description will be given by exemplifying a case where a surface and a back surface of the silicon carbide layer 10 are a face inclined by 0° (0 degree) or more and 8° (8 degree) or less with respect to the silicon face and a face inclined by 0° (0 degree) or more and 8° (8 degree) or less with respect to the carbon face, respectively. The surface of the silicon carbide layer 10 has an off-angle of 0° (0 degree) or more and 8° (8 degree) or less with respect to the silicon face.

The drain region 12 is n⁺-type SiC. The drain region 12 contains, for example, nitrogen (N) as an n-type impurity. An n-type impurity concentration of the drain region 12 is, for example, 1×10¹⁸ cm⁻³ or more and 1×10²¹ cm⁻³ or less.

The drift region 14 is provided on the drain region 12. The drift region 14 is n⁻-type SiC. The drift region 14 contains, for example, nitrogen (N) as an n-type impurity.

An n-type impurity concentration of the drift region 14 is lower than the n-type impurity concentration of the drain region 12. The n-type impurity concentration of the drift region 14 is, for example, 1×10¹⁵ cm⁻³ or more and 2×10¹⁶ cm⁻³ or less. The drift region 14 is, for example, an SiC epitaxial growth layer formed on the drain region 12 by epitaxial growth.

A thickness of the drift region 14 is, for example, 5 μm or more and 100 μm or less.

The p-well region 16 is provided on a partial surface of the drift region 14. The p-well region 16 is p-type SiC. The p-well region 16 contains, for example, aluminum (Al) as a p-type impurity. A p-type impurity concentration of the p-well region 16 is, for example, 1×10¹⁶ cm⁻³ or more and 1×10²⁰ cm⁻³ or less.

A depth of the p-well region 16 is, for example, 0.4 μm or more and 0.8 μm or less. The p-well region 16 functions as a channel region of the MOSFET 100.

The source region 18 is provided on a partial surface of the p-well region 16. The source region 18 is n⁺-type SiC. The source region 18 contains, for example, phosphorus (P) as an n-type impurity. An n-type impurity concentration of the source region 18 is, for example, 1×10¹⁸ cm⁻³ or more and 1×10²² cm⁻³ or less.

A depth of the source region 18 is shallower than the depth of the p-well region 16. The depth of the source region 18 is, for example, 0.2 μm or more and 0.4 μm or less.

The p-well contact region 20 is provided on a partial surface of the p-well region 16. The p-well contact region 20 is provided next to the source region 18. The p-well contact region 20 is p⁺-type SiC.

The p-well contact region 20 contains, for example, aluminum as a p-type impurity. A p-type impurity concentration of the p-well contact region 20 is, for example, 1×10¹⁸ cm⁻³ or more and 1×10²² cm⁻³ or less.

A depth of the p-well contact region 20 is shallower than the depth of the p-well region 16. The depth of the p-well contact region 20 is, for example, 0.2 μm or more and 0.4 μm or less

The gate insulating layer 28 is provided between the silicon carbide layer 10 and the gate electrode 30. The gate insulating layer 28 is provided between the drift region 14 and the p-well region 16, and the gate electrode 30. The gate insulating layer 28 is provided on the drift region 14 and the p-well region 16. The gate insulating layer 28 is continuously formed on surfaces of the drift region 14 and the p-well region 16.

The gate insulating layer 28 is silicon oxide. The gate insulating layer 28 is, for example, silicon dioxide. The gate insulating layer 28 is an example of a silicon oxide layer.

The gate insulating layer 28 contains nitrogen (N), carbon (C), and hydrogen (H).

A thickness of the gate insulating layer 28 is, for example, 30 nm or more and 100 nm or less. The gate insulating layer 28 functions as a gate insulating layer of the MOSFET 100. The thickness of the gate insulating layer 28 is, for example, 40 nm or more and 50 nm or less.

The interface termination region 40 is disposed between the silicon carbide layer 10 and the gate insulating layer 28. The interface termination region 40 is disposed between the drift region 14 and the p-well region 16, and the gate insulating layer 28. The interface termination region 40 contains nitrogen (N) as a termination element that terminates a dangling bond of the silicon carbide layer 10. The interface termination region 40 is an example of a region.

A nitrogen concentration in the interface termination region 40 is equal to or more than 1×10²¹ cm⁻³.

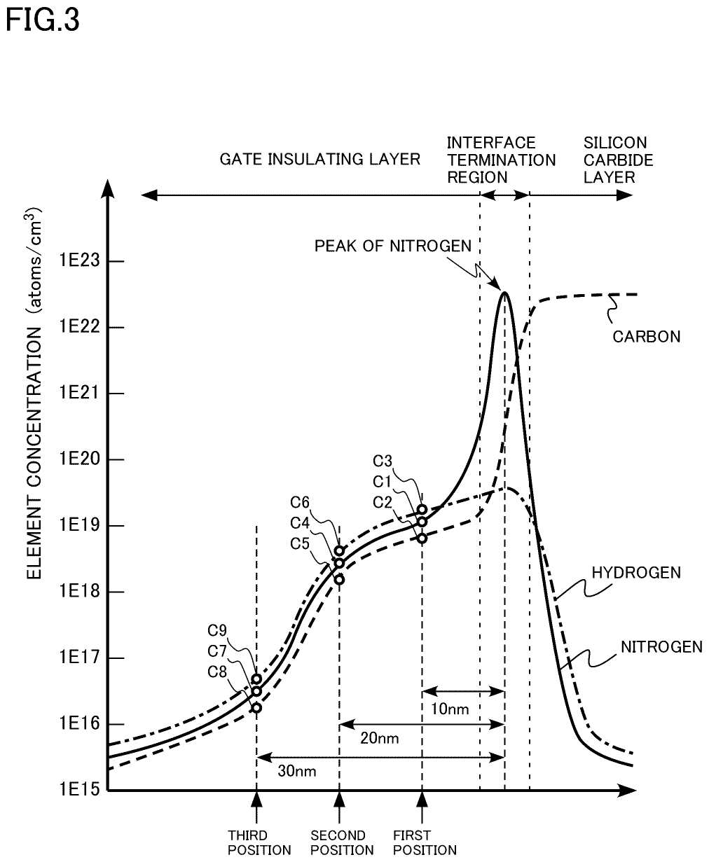

FIG. 3 is a graph illustrating element concentration distributions of the semiconductor device of the first embodiment. FIG. 3 is a graph illustrating element concentration distributions in the gate insulating layer 28, the interface termination region 40, and the silicon carbide layer 10.

FIG. 3 illustrates concentration distributions of nitrogen (N), carbon (C), and hydrogen (H). In FIG. 3, a solid line indicates the nitrogen concentration distribution, a dotted line indicates the carbon concentration distribution, and an alternate long and short dash line indicates the hydrogen concentration distribution.

The nitrogen concentration distribution has a peak in the interface termination region 40. A nitrogen concentration at the peak is, for example, equal to or more than 1×10²¹ cm⁻³. A full width at half maximum for the peak of the nitrogen concentration distribution is, for example, 1 nm or less. Nitrogen is segregated at an interface between the silicon carbide layer 10 and the gate insulating layer 28.

The nitrogen concentration at the peak of the nitrogen concentration distribution is, for example, 1×10²¹ cm⁻³ or more and 4×10²³ cm⁻³ or less. In order to ensure the termination, the nitrogen concentration at the peak is preferably equal to or more than 1×10²² cm⁻³. On the other hand, charge trapping occurs if there is excess nitrogen, and thus the nitrogen concentration at the peak is preferably 1×10²³ cm⁻³ or less. Typically, the nitrogen concentration at the peak is about 5.0×10²² cm⁻³, that is, 5.0×10²² cm⁻³ 5%. When the nitrogen concentration at the peak is in the above range, a capacitor including the gate electrode 30, the gate insulating layer 28, and the silicon carbide layer 10 exhibits good characteristics without charge trapping. An area density of nitrogen at the interface is preferably 1×10¹⁴ cm⁻² or more and 2.5×10¹⁵ cm⁻² or less. Typically, the area density of nitrogen is about 1.4×10¹⁵ cm⁻², that is, 1.4×10¹⁵ cm⁻²±5%. When the area density of nitrogen is in the above range, the capacitor including the gate electrode 30, the gate insulating layer 28, and the silicon carbide layer 10 exhibits good characteristics with less charge trapping.

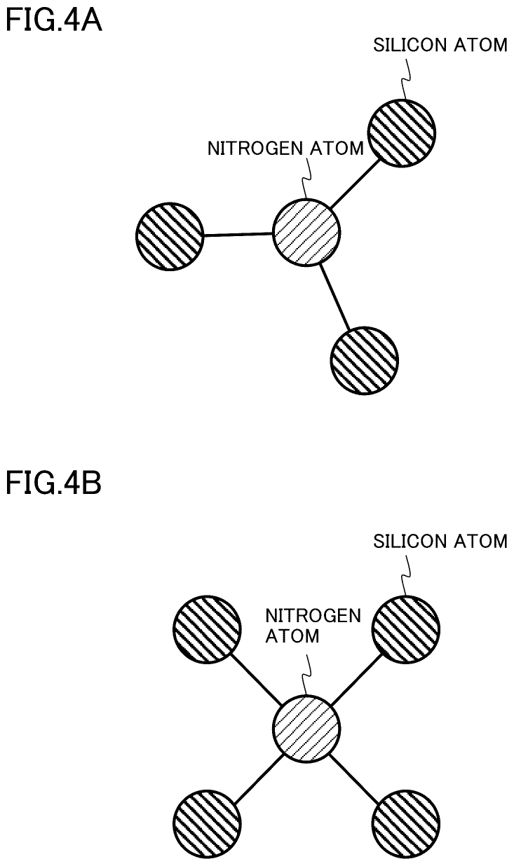

FIGS. 4A and 4B are schematic views illustrating bonding states of nitrogen atoms in the semiconductor device according to the first embodiment. FIG. 4A illustrates a case where a nitrogen atom is tricoordinated, and FIG. 4B illustrates a case where a nitrogen atom is tetracoordinated.

In the case of being tricoordinated as illustrated in FIG. 4A, the nitrogen atom is bonded to three silicon atoms. In the case of being tetracoordinated as illustrated in FIG. 4B, the nitrogen atom is bonded to four silicon atoms.

In the interface termination region 40, the amount of nitrogen atoms each being bonded to three silicon atoms is larger than the amount of nitrogen atoms each being bonded to four silicon atoms. In other words, in the interface termination region 40, the amount of tricoordinate nitrogen atoms is larger than the amount of tetracoordinate nitrogen atoms.

For example, 90% or more of nitrogen atoms present in the interface termination region 40 are the tricoordinate nitrogen atoms. The concentration of the three-coordination nitrogen atoms is, for example, equal to or more than 1×10²² cm⁻³.

The tricoordinate nitrogen atoms present in the interface termination region 40 terminate the dangling bond on the surface of the silicon carbide layer 10.

Nitrogen atoms substitutes carbon atoms of a bilayer constituting the uppermost layer of the silicon carbide layer 10. Excess silicon atoms and carbon atoms are released to the gate insulating layer 28 side, and the termination element is eventually bonded to the silicon carbide layer 10 by tricoordination. The nitrogen atoms are at positions of carbon atoms in a crystal structure of silicon carbide. Some of silicon atoms of the outermost surface are absorbed to the gate insulating layer 28 side, and the nitrogen atoms are tricoordinated with silicon atoms of the silicon carbide layer 10.

As illustrated in FIG. 3, a first concentration (C1 in FIG. 3) of nitrogen at a first position 10 nm away from the peak of the nitrogen concentration distribution toward the gate insulating layer 28 is 1×10¹⁸ cm⁻³ or more and 1×10²¹ cm⁻³ or less. In addition, a second concentration (C2 in FIG. 3) of carbon at the first position is 1×10¹⁸ cm⁻³ or more and 1×10²¹ cm⁻³ or less. In addition, a third concentration (C3 in FIG. 3) of hydrogen at the first position is 1×10¹⁸ cm⁻³ or more and 1×10²¹ cm⁻³ or less.

For example, the first concentration C1 is 1×10¹⁹ cm⁻³ or more and 1×10²⁰ cm⁻³ or less, the second concentration C2 is 1×10¹⁹ cm⁻³ or more and 1×10²⁰ cm⁻³ or less, and the third concentration C3 is 1×10¹⁹ cm⁻³ or more and 1×10²⁰ cm⁻³ or less.

The second concentration C2 is 80% or more and 120% or less of the first concentration C1. In addition, the third concentration C3 is 80% or more and 120% or less of the first concentration C1.

For example, the second concentration C2 is 90% or more and 110% or less of the first concentration C1. In addition, for example, the third concentration C3 is 90% or more and 110% or less of the first concentration C1.

As illustrated in FIG. 3, for example, a fourth concentration (C4 in FIG. 3) of nitrogen at a second position 20 nm away from the peak of the nitrogen concentration distribution toward the gate insulating layer 28 is 1×10¹⁸ cm⁻³ or more and 1×10²¹ cm⁻³ or less. In addition, for example, a fifth concentration (C5 in FIG. 3) of carbon at the second position is 1×10¹⁸ cm⁻³ or more and 1×10²¹ cm⁻³ or less. In addition, for example, a sixth concentration (C6 in FIG. 3) of hydrogen at the second position is 1×10¹⁸ cm⁻³ or more and 1×10²¹ cm⁻³ or less.

For example, the fifth concentration C5 is 80% or more and 120% or less of the fourth concentration C4. In addition, for example, the sixth concentration C6 is 80% or more and 120% or less of the fourth concentration C4.

For example, the fifth concentration C5 is 90% or more and 110% or less of the fourth concentration C4. In addition, for example, the sixth concentration C6 is 90% or more and 110% or less of the fourth concentration C4.

As illustrated in FIG. 3, for example, a seventh concentration (C7 in FIG. 3) of nitrogen at a third position 30 nm away from the peak of the nitrogen concentration distribution toward the gate insulating layer 28 is less than 1×10¹⁸ cm⁻³. In addition, for example, an eighth concentration (C8 in FIG. 3) of carbon at the third position is less than 1×10¹⁸ cm⁻³. In addition, a ninth concentration (C9 in FIG. 3) of hydrogen at the third position is less than 1×10¹⁸ cm⁻³.

In SIMS measurement, a measurement limit of nitrogen, carbon, and hydrogen are about 1×10¹⁸ cm⁻³. In the SIMS measurement, a measurement amount of the concentration of each element at the third position is preferably less than the measurement limit. In this case, charge trapping in an insulating film hardly affects device characteristics.

For example, the eighth concentration C8 is 80% or more and 120% or less of the seventh concentration C7. In addition, for example, the ninth concentration C9 is 80% or more and 120% or less of the seventh concentration C7.

For example, the eighth concentration C8 is 90% or more and 110% or less of the seventh concentration C7. In addition, for example, the ninth concentration C9 is 90% or more and 110% or less of the seventh concentration C7.

The concentrations of nitrogen, carbon, and hydrogen can be favorably matched with each other by a method for manufacturing the semiconductor device of the first embodiment to be described later. If precise concentration measurement below the measurement limit of the SIMS measurement is required, it is effective to use hard X-ray photoelectron spectroscopy (HAXPES) measurement or the like.

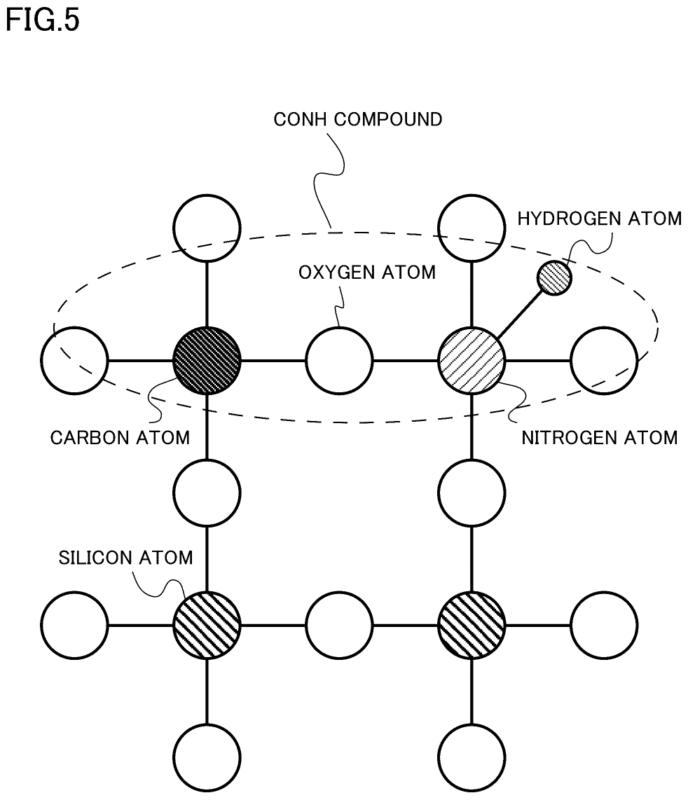

FIG. 5 is an explanatory view of the gate insulating layer of the semiconductor device of the first embodiment. FIG. 5 illustrates a compound including a carbon atom, oxygen atoms, a nitrogen atom, and a hydrogen atom contained in the gate insulating layer 28. Hereinafter, the compound including the carbon atom, the oxygen atoms, the nitrogen atom, and the hydrogen atom illustrated in FIG. 5 is referred to as a CONH compound.

As illustrated in FIG. 5, in the CONH compound, the carbon atom, the oxygen atoms, the nitrogen atom, and the hydrogen atom are close to each other in silicon oxide to form the compound. In the CONH compound, the carbon atom and the oxygen atom are bonded to each other, the oxygen atom and the nitrogen atom are bonded to each other, and the nitrogen atom and the hydrogen atom are bonded to each other.

In the CONH compound, each of the carbon atom and the nitrogen atom substitutes for a silicon atom of the silicon oxide. In other words, in the CONH compound, each of the carbon atom and the nitrogen atom is present at a silicon site of silicon dioxide. In the CONH compound, the oxygen atom is present between the carbon atom and the nitrogen atom. The carbon atom and the oxygen atom are bonded by a single bond, and the nitrogen atom and the oxygen atom are bonded by a single bond. The carbon atom constituting the CONH compound is tetracoordinated.

For example, most of carbon atoms, nitrogen atoms, and hydrogen atoms present in a region 10 nm or more away from the peak of the nitrogen concentration distribution toward the gate insulating layer 28 constitute the CONH compounds. Therefore, for example, as illustrated in FIG. 3, a distribution of the carbon atoms, a distribution of the nitrogen atoms, and a distribution of the hydrogen atoms overlap in the region 10 nm or more away from the peak of the nitrogen concentration distribution toward the gate insulating layer 28.

For example, as the distance from the peak of the nitrogen concentration distribution increases, an amount of the CONH compounds in the gate insulating layer 28 decreases. Therefore, as illustrated in FIG. 3, the concentration of carbon, the concentration of nitrogen, and the concentration of hydrogen in the gate insulating layer 28 decrease as the distance from the peak of the nitrogen concentration distribution increases.

Since most of hydrogen atoms in the gate insulating layer 28 constitute the CONH compounds, an amount of hydrogen atoms bonded to nitrogen atoms in the gate insulating layer 28 is larger than an amount of hydrogen atoms bonded to silicon atoms.

The gate electrode 30 is provided on the gate insulating layer 28. The gate electrode 30 sandwiches the gate insulating layer 28 with the silicon carbide layer 10. The gate electrode 30 sandwiches the gate insulating layer 28 with the drift region 14. The gate electrode 30 sandwiches the gate insulating layer 28 with the p-well region 16.

The gate electrode 30 is, for example, polycrystalline silicon containing an n-type impurity or a p-type impurity.

The interlayer insulating film 32 is formed on the gate electrode 30. The interlayer insulating film 32 is, for example, a silicon oxide film.

The source electrode 34 is electrically connected to the source region 18 and the p-well contact region 20. The source electrode 34 also functions as a p-well electrode that applies an electric potential to the p-well region 16.

The source electrode 34 is formed by, for example, stacking a barrier metal layer of nickel (Ni) and a metal layer of aluminum on the barrier metal layer. The barrier metal layer of nickel and the silicon carbide layer may react to form nickel silicide (NiSi, Ni₂Si, or the like). The barrier metal layer of nickel and the metal layer of aluminum may form an alloy by reaction.

The drain electrode 36 is provided on the silicon carbide layer 10 on the side opposite to the source electrode 34, that is, on the back surface side. The drain electrode 36 is, for example, nickel. Nickel may react to the drain region 12 to form nickel silicide (NiSi, Ni₂Si, or the like).

In the first embodiment, the n-type impurity is, for example, nitrogen or phosphorus. Arsenic (As) or antimony (Sb) can also be applied as the n-type impurity.

In the first embodiment, the p-type impurity is, for example, aluminum. Boron (B), gallium (Ga), or indium (In) can also be applied as the p-type impurity.

Next, an example of the method for manufacturing the semiconductor device of the first embodiment will be described.

In the method for manufacturing the semiconductor device of the first embodiment, a silicon oxide film is formed on a surface of a silicon carbide layer, a first heat treatment is performed at a temperature of 1100° C. or higher and 1300° C. or lower in an atmosphere containing nitrogen oxide gas after the silicon oxide film is formed, a second heat treatment is performed at a temperature of 100° C. or higher and 600° C. or lower in an atmosphere containing oxygen gas after the first heat treatment, a third heat treatment is performed at a temperature of 100° C. or higher and 600° C. or lower in an atmosphere containing hydrogen gas after the second heat treatment, and a gate electrode is formed on the silicon oxide film after the third heat treatment.

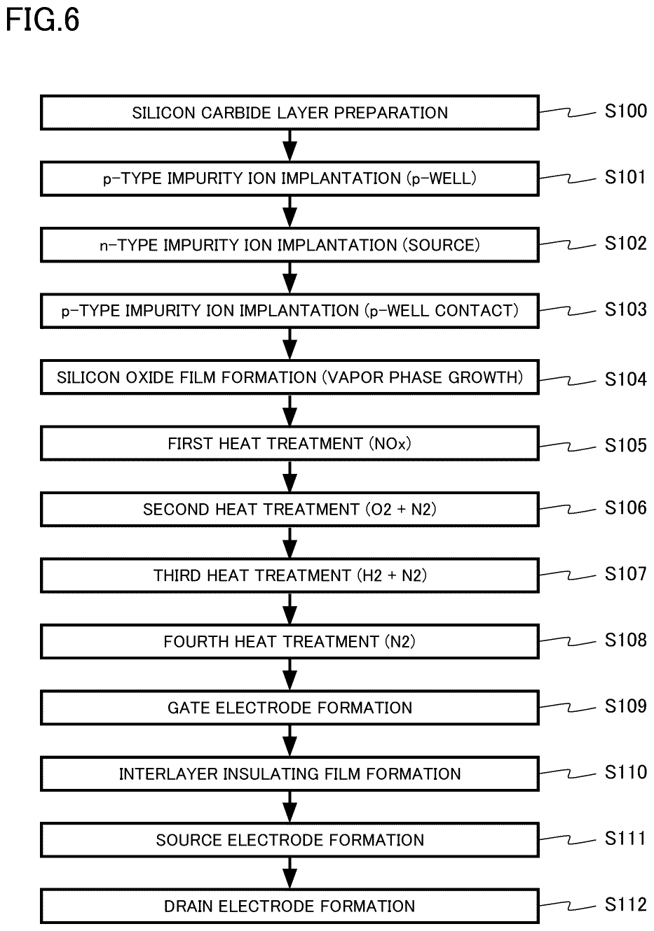

FIG. 6 is a flowchart of a process of the method for manufacturing the semiconductor device of the first embodiment.

As illustrated in FIG. 6, the method for manufacturing the semiconductor device of the first embodiment includes silicon carbide layer preparation (step S100), p-type impurity ion implantation (step S101), n-type impurity ion implantation (step S102), p-type impurity ion implantation (step S103), silicon oxide film formation (step S104), a first heat treatment (step S105), a second heat treatment (step S106), a third heat treatment (step S107), a fourth heat treatment (step S108), gate electrode formation (step S109), interlayer insulating film formation (step S110), source electrode formation (step S111), and drain electrode formation (step S112).

In step S100, the silicon carbide layer 10 is prepared. The silicon carbide layer 10 includes the drain region 12 of the n⁺-type and the drift region 14 of the n⁻-type. The drift region 14 is formed, for example, on the drain region 12 by an epitaxial growth method.

The drain region 12 contains nitrogen as an n-type impurity. An n-type impurity concentration of the drain region 12 is, for example, 1×10¹⁸ cm⁻³ or more and 1×10²¹ cm⁻³ or less.

The drift region 14 contains nitrogen as an n-type impurity. The n-type impurity concentration of the drift region 14 is, for example, 1×10¹⁵ cm⁻³ or more and 2×10¹⁶ cm⁻³ or less. A thickness of the drift region 14 is, for example, 5 μm or more and 100 μm or less.

In step S101, first, a first mask material is formed by patterning using photolithography and etching. Then, aluminum as a p-type impurity is ion-implanted into the drift region 14 using the first mask material as an ion implantation mask. The p-well region 16 is formed by ion implantation.

In step S102, first, a second mask material is formed by patterning using photolithography and etching. Then, phosphorus as an n-type impurity is ion-implanted into the drift region 14 to form the source region 18 using the second mask material as an ion implantation mask.

In step S103, a third mask material is formed by patterning using photolithography and etching. Aluminum as a p-type impurity is ion-implanted into the drift region 14 to form the p-well contact region 20 using the third mask material as an ion implantation mask.

In step S104, a silicon oxide film is formed on the silicon carbide layer 10. The silicon oxide film eventually becomes the gate insulating layer 28.

The silicon oxide film is formed by, for example, vapor phase growth. The silicon oxide film is formed by, for example, a chemical vapor deposition method (CVD method) or a physical vapor deposition method (PVD method). The silicon oxide film is a deposited film. A thickness of the silicon oxide film is, for example, 30 nm or more and 100 nm or less. The thickness of the silicon oxide film is, for example, 40 nm or more and 50 nm or less.

The silicon oxide film is, for example, a silicon oxide film formed by a CVD method using tetraethyl orthosilicate (TEOS) as a source gas. In addition, the silicon oxide film is, for example, a silicon oxide film formed by a CVD method using dichlorosilane gas (SiH₂Cl₂) and dinitrogen monoxide gas (N₂O) as source gases.

In step S105, the first heat treatment is performed. The first heat treatment is performed in an atmosphere containing nitrogen oxide gas (NOx). The nitrogen oxide gas is, for example, nitrogen monoxide gas (NO). In addition, the nitrogen oxide gas is, for example, dinitrogen monoxide gas (N₂O).

For example, the nitrogen oxide gas (NOx) is supplied to a reaction furnace containing the silicon carbide layer 10 to perform a heat treatment.

The temperature of the first heat treatment is 1100° C. or higher and 1300° C. or lower.

The interface termination region 40 is formed at an interface between the silicon carbide layer 10 and the silicon oxide film by the first heat treatment.

The first heat treatment also functions as densify annealing of the silicon oxide film. The silicon oxide film becomes a high-density film by the first heat treatment.

By the first heat treatment, the surface of the silicon carbide layer 10 is oxidized, and excess carbon diffuses into the silicon oxide film.

In step S106, the second heat treatment is performed. The second heat treatment is performed in an atmosphere containing oxygen gas (O₂). The oxygen gas (O₂) is diluted with, for example, nitrogen gas (N₂) or argon gas (Ar).

For example, the oxygen gas (O₂) diluted with the nitrogen gas (N₂) is supplied to the reaction furnace containing the silicon carbide layer 10 to perform a heat treatment.

The temperature of the second heat treatment is 100° C. or higher and 600° C. or lower.

An oxygen vacancy in the silicon oxide film is buried by the second heat treatment. The silicon oxide film with the reduced oxygen vacancy is formed by the second heat treatment.

In step S107, the third heat treatment is performed. The third heat treatment is performed in an atmosphere containing hydrogen gas (H₂). The hydrogen gas (H₂) may be diluted with, for example, nitrogen gas (N₂) or argon gas (Ar).

For example, the hydrogen gas (H₂) diluted with the nitrogen gas (N) is supplied to the reaction furnace containing the silicon carbide layer 10 to perform a heat treatment.

A partial pressure of the hydrogen gas (H₂) in the atmosphere of the third heat treatment is, for example, 5% or more and 20% or less.

The temperature of the third heat treatment is 100° C. or higher and 600° C. or lower. The temperature of the third heat treatment is, for example, equal to or lower than the temperature of the second heat treatment.

The CONH compounds are formed in the silicon oxide film by the third heat treatment.

In step S108, the fourth heat treatment is performed. The fourth heat treatment is performed in an atmosphere in which a partial pressure of hydrogen gas is lower than the partial pressure of the hydrogen gas in the atmosphere of the third heat treatment. The partial pressure of the hydrogen gas in the fourth heat treatment is, for example, less than 5%.

The fourth heat treatment is performed, for example, in an atmosphere containing nitrogen gas (N₂). The fourth heat treatment is performed, for example, in a nitrogen gas atmosphere.

The fourth heat treatment is performed, for example, in an atmosphere containing argon gas (Ar). The fourth heat treatment is performed, for example, in an argon gas atmosphere.

For example, the nitrogen gas (N₂) is supplied to the reaction furnace containing the silicon carbide layer 10 to perform a heat treatment.

A temperature of the fourth heat treatment is 100° C. or higher and 600° C. or lower. The temperature of the fourth heat treatment is, for example, equal to or lower than the temperature of the second heat treatment or equal to or lower than the temperature of the third heat treatment.

By the fourth heat treatment, interstitial hydrogen in the silicon oxide film decreases.

In step S109, the gate electrode 30 is formed on the gate insulating layer 28. The gate electrode 30 is, for example, polycrystalline silicon containing an n-type impurity or a p-type impurity.

In step S110, the interlayer insulating film 32 is formed on the gate electrode 30. The interlayer insulating film 32 is, for example, a silicon oxide film.

In step S111, the source electrode 34 is formed. The source electrode 34 is formed on the source region 18 and the p-well contact region 20. The source electrode 34 is formed by sputtering of nickel (Ni) and aluminum (Al), for example.

In step S112, the drain electrode 36 is formed. The drain electrode 36 is formed on the back surface side of the silicon carbide layer 10. The drain electrode 36 is formed by, for example, sputtering of nickel.

The MOSFET 100 illustrated in FIG. 1 is formed according to the above manufacturing method.

Next, a function and an effect of the semiconductor device of the first embodiment and the method for manufacturing the semiconductor device will be described.

When a MOSFET is formed using silicon carbide, there is a problem that carrier mobility decreases. One factor that decreases the carrier mobility is considered to be an interface state between a silicon carbide layer and a gate insulating layer. The interface state is considered to be generated by dangling bonds present on a surface of the silicon carbide layer.

The MOSFET 100 of the first embodiment includes the interface termination region 40 in which nitrogen is segregated between the silicon carbide layer 10 and the gate insulating layer 28. The dangling bonds are reduced by the interface termination region 40. Therefore, the MOSFET 100 in which the decrease in the carrier mobility is suppressed is achieved.

In addition, when a MOSFET is formed using silicon carbide, there is a problem that carrier mobility decreases or a threshold voltage fluctuates. In addition, there is a problem that a leakage current of a gate insulating layer increases or reliability of the gate insulating layer decreases. One factor that causes the above problems is considered to be a harmful defect present in the gate insulating layer.

The harmful defect present in the gate insulating layer is considered to be, for example, oxygen deficiency in silicon oxide or a defect caused by carbon or nitrogen contained in silicon oxide. The defect present in the gate insulating layer forms a trap state in the gate insulating layer, and thus is considered to be a factor that causes the above problems.

In the MOSFET 100 of the first embodiment, an amount of harmful defects in the gate insulating layer 28 is reduced. Therefore, the decrease in the carrier mobility, the fluctuation in the threshold voltage, the increase in the leakage current of the gate insulating layer, or the decrease in the reliability of the gate insulating layer due to the harmful defects is suppressed. Details will be described hereinafter.

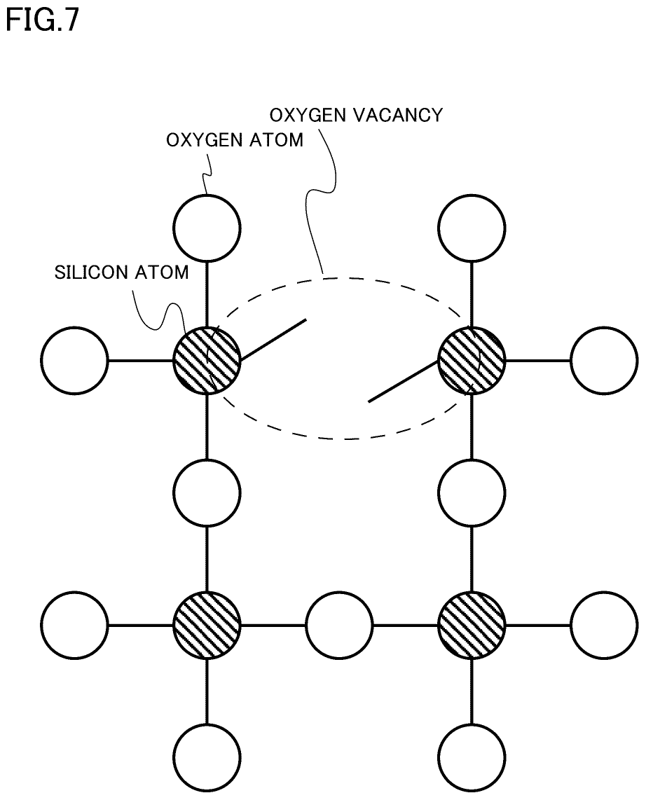

FIG. 7 is an explanatory view of the function and the effect of the semiconductor device of the first embodiment. FIG. 7 illustrates an oxygen vacancy in silicon oxide. The oxygen vacancy in the silicon oxide is accompanied by dangling bonds of silicon atoms.

The dangling bonds of the silicon atoms form a trap state in the gate insulating layer. For example, when charge is trapped in the trap state, the carrier mobility decreases, the threshold voltage fluctuates, or the leakage current of the gate insulating layer increases. Therefore, it is desirable to reduce an amount of oxygen vacancies in the gate insulating layer.

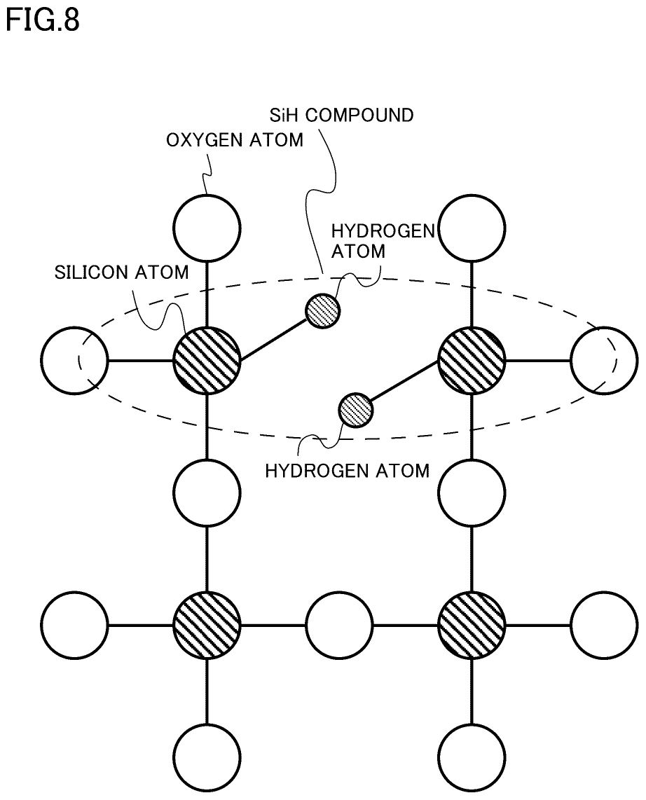

FIG. 8 is an explanatory view of the function and the effect of the semiconductor device of the first embodiment. FIG. 8 illustrates a structure in which hydrogen atoms are bonded to the dangling bonds of the silicon atoms generated by the oxygen vacancy in the silicon oxide. Hereinafter, the structure in which the hydrogen atoms are bonded to the dangling bonds of the silicon atoms generated by the oxygen vacancy is referred to as an SiH compound.

For example, when a heat treatment is performed on the silicon oxide in an atmosphere containing hydrogen, the SiH compounds, and the dangling bonds of the silicon atoms disappear. However, for example, there is a high possibility that hydrogen atoms are released from the SiH compounds in the gate insulating layer during the operation of the MOSFET and the dangling bonds of the silicon atoms are formed again. Therefore, it is desirable to reduce the amount of oxygen vacancies in the gate insulating layer of the MOSFET as much as possible.

The amount of oxygen vacancies in the silicon oxide increases as a temperature of a heat treatment applied to the silicon oxide increases. This is because entropy increases as the temperature of the heat treatment increases.

In the method for manufacturing the semiconductor device of the first embodiment, the interface termination region 40 is formed at the interface between the silicon carbide layer 10 and the silicon oxide film by the first heat treatment performed in the atmosphere containing nitrogen oxide gas (NOx). The first heat treatment is performed at a high temperature of 1100° C. or higher and 1300° C. or lower. Therefore, a large amount of oxygen vacancies are formed in the silicon oxide film due to the increase in entropy.

In the method for manufacturing the semiconductor device of the first embodiment, the second heat treatment is performed after the first heat treatment. The second heat treatment is performed in an atmosphere containing oxygen gas (O₂). The oxygen vacancies are buried by the second heat treatment, and the amount of oxygen vacancies in the silicon oxide film decreases. As the amount of oxygen vacancies in the silicon oxide film decreases, formation of the SiH compound is suppressed even if a heat treatment is performed in an atmosphere containing hydrogen after the second heat treatment, for example.

The second heat treatment is performed at 100° C. or higher and 600° C. or lower. When the temperature of the second heat treatment is 600° C. or lower, oxidation of the surface of the silicon carbide layer 10 is suppressed. Therefore, new diffusion of carbon into the silicon oxide film is suppressed.

The temperature of the second heat treatment is preferably 200° C. or higher and 500° C. or lower, and more preferably 300° C. or higher and 400° C. or lower. When the above lower limit value is satisfied, the amount of oxygen vacancies decreases. When the above upper limit value is satisfied, the oxidation of the surface of the silicon carbide layer 10 can be suppressed.

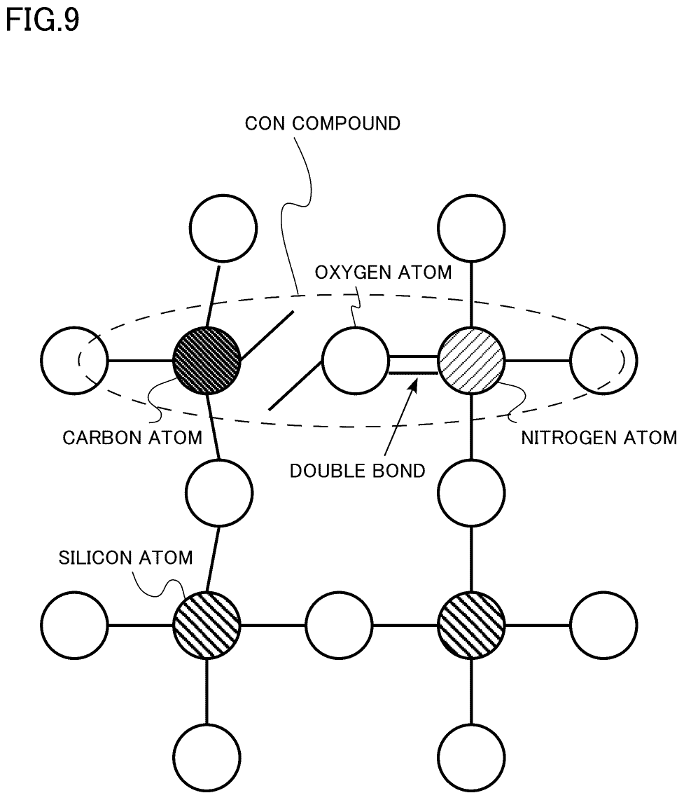

FIG. 9 is an explanatory view of the function and the effect of the semiconductor device of the first embodiment. FIG. 9 illustrates a defect caused by carbon and nitrogen in silicon oxide. A carbon atom, oxygen atoms, and a nitrogen atom are close to each other in the silicon oxide to form a compound. Hereinafter, this compound is referred to as a CON compound.

In the CON compound, each of the carbon atom and the nitrogen atom substitutes for a silicon atom of the silicon oxide. In other words, in the CON compound, each of the carbon atom and the nitrogen atom is present at a silicon site of silicon dioxide. The oxygen atom is present between the carbon atom and the nitrogen atom. The nitrogen atom and the oxygen atom are bonded by a double bond. Each of the carbon atom and the nitrogen atom has a dangling bond. The carbon atom constituting the CON compound is tricoordinated.

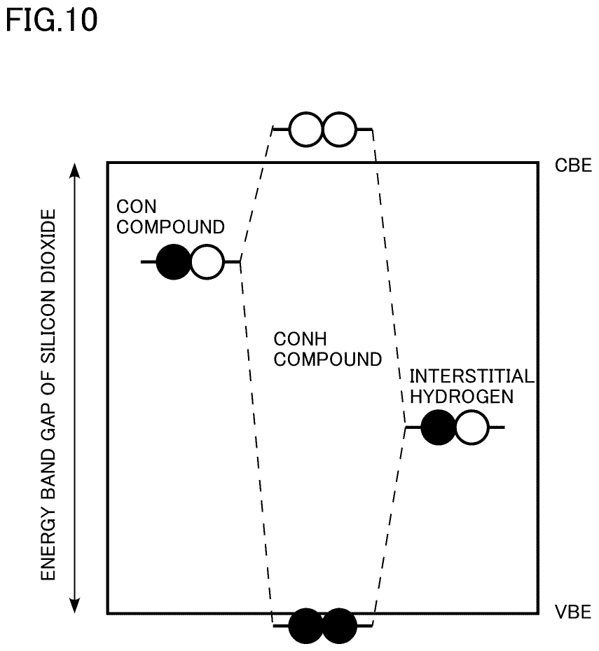

FIG. 10 is an explanatory view of the function and the effect of the semiconductor device of the first embodiment. FIG. 10 is a band diagram of silicon dioxide.

As illustrated in FIG. 10, the CON compound forms a trap state in an energy band of silicon dioxide. For example, the CON compound emits electrons and has positive fixed charge. Therefore, for example, the threshold voltage of the MOSFET decreases. In addition, for example, the charge is trapped in the trap state during the operation of the MOSFET, so that the threshold voltage of the MOSFET fluctuates. In addition, for example, the presence of the trap state causes the decrease in the carrier mobility or the increase in the leakage current of the gate insulating layer. Therefore, it is desirable to reduce an amount of the CON compounds which are harmful defects in the gate insulating layer.

In the method for manufacturing the semiconductor device of the first embodiment, the surface of the silicon carbide layer 10 is oxidized by the first heat treatment performed in the atmosphere containing the nitrogen oxide gas (NOx), and carbon is released into the silicon oxide film. Carbon released into the silicon oxide film is bonded to nitrogen in the nitrogen oxide gas to form the CON compound.

In the first heat treatment (nitrogen oxide heat treatment), since nitrogen is introduced into the silicon oxide film, nitrogen interacts with excess carbon to form the CON compound and stabilizes. At this time, both carbon and nitrogen enter silicon sites in the silicon oxide film. Once the CON compound is formed, carbon and nitrogen are contained at the silicon sites, and thus cannot be removed by the second heat treatment (treatment with the oxygen gas).

Since this CON compound traps charge, mobility degradation of an MOS interface and a decrease in reliability of an insulating film are caused. In order to introduce a sufficient amount of nitrogen into the interface, the first heat treatment at a high temperature for a long time is required. However, when the first heat treatment is performed at a high temperature for a long time, a large amount of the CON compounds is generated in the insulating film due to a large amount of carbon released into the silicon oxide film. Therefore, the mobility degradation of the MOS interface and the decrease in the reliability of the insulating film are caused.

On the other hand, if only nitrogen is present in the silicon oxide film and carbon is not present, nitrogen enters an oxygen position in the silicon oxide film. Therefore, nitrogen can be removed from the silicon oxide film by oxidation by the first heat treatment (nitrogen oxide heat treatment) or the second heat treatment (treatment with the oxygen gas). This state is also established when the amount of nitrogen is larger than the amount of carbon. That is, the CON structure is formed by nitrogen in the same amount as the same amount of carbon, and an excess amount of nitrogen larger than the amount of carbon enters the oxygen position in the silicon oxide film. Therefore, nitrogen contained in an amount larger than the amount of carbon can be removed from the insulating film by oxidation by the first heat treatment (nitrogen oxide heat treatment) or the second heat treatment (treatment with the oxygen gas).

If only carbon is present and nitrogen is not present, carbon enters the oxygen position in the silicon oxide film. Therefore, carbon can be removed from the silicon oxide film by oxidation by the second heat treatment (treatment with the oxygen gas). This state is also established when the amount of carbon is larger than the amount of nitrogen. That is, the CON structure is formed by carbon in the same amount as the amount of nitrogen, and an excess amount of carbon larger than the amount of nitrogen enters the oxygen position in the silicon oxide film, so that carbon contained in an amount larger than the amount of nitrogen can be removed from the insulating film by oxidation by the second heat treatment (treatment with the oxygen gas).

That is, the surface of the silicon carbide layer 10 is oxidized by the first heat treatment, excess carbon diffuses into the silicon oxide film, and interacts with nitrogen introduced into the silicon oxide film by the first heat treatment to generate the CON compounds in the silicon oxide film. Nitrogen or carbon remaining at the oxygen position in the silicon oxide film is removed from the silicon oxide film by the second heat treatment. In this manner, the CON compounds are distributed to gradually decrease in amount from an interface side between the silicon carbide layer and the insulating film toward an interface between the insulating film and an electrode.

In the method for manufacturing the semiconductor device of the first embodiment, the third heat treatment is performed after the first heat treatment and the second heat treatment. The third heat treatment is performed in an atmosphere containing hydrogen gas (H₂). By the third heat treatment, hydrogen atoms derived from the hydrogen gas are bonded to nitrogen atoms of the CON compounds so that the CON compounds are converted into the CONH compounds illustrated in FIG. 5.

As illustrated in FIG. 10, the CON compound and the interstitial hydrogen each forms the trap state in the energy band of silicon dioxide. Meanwhile, the inventors have studied and found that the trap state in the energy band disappears when the interstitial hydrogen is bonded to the CON compound to form the CONH compound.

The CONH compound in silicon oxide is more stable in energy than a combination of the CON compound and the interstitial hydrogen. An energy difference between the CONH compound and the combination of the CON compound and the interstitial hydrogen is 12.0 eV, and the energy difference is extremely large.

The inventors have studied and found that the CONH compound is the most stable among structures that can be formed in a state where carbon atoms, oxygen atoms, nitrogen atoms, and hydrogen atoms are close to each other in silicon oxide. Therefore, once the CONH compound is formed in the gate insulating layer 28, decomposition of the CONH compound hardly occurs even during the operation of the MOSFET, for example.

In the method for manufacturing the semiconductor device of the first embodiment, the CON compounds in the gate insulating layer 28 is converted into the CONH compounds by the third heat treatment, and the amount of the CON compounds in the gate insulating layer 28 can be reduced.

The temperature of the third heat treatment is 100° C. or higher and 600° C. or lower. The temperature of the third heat treatment is preferably 200° C. or higher and 500° C. or lower, and more preferably 300° C. or higher and 400° C. or lower. When the above lower limit value is satisfied, the conversion from the CON compounds to the CONH compounds is promoted. When the above lower limit value is satisfied, an increase of the oxygen vacancies in the gate insulating layer 28 due to the increase in entropy can be suppressed.

The temperature of the third heat treatment is preferably equal to or lower than the temperature of the second heat treatment from the viewpoint of suppressing the increase of the oxygen vacancies in the gate insulating layer 28.

The third heat treatment needs to be performed after the second heat treatment. In other words, the second heat treatment needs to be performed before the third heat treatment.

If the third heat treatment performed in an atmosphere containing hydrogen gas (H₂) is performed before the second heat treatment, the oxygen vacancies in the gate insulating layer 28 are converted into the SiH compounds. Even if the second heat treatment is performed in the atmosphere containing the oxygen gas (O₂) after the conversion into the SiH compounds, the oxygen vacancies once converted into the SiH compounds cannot be buried. Therefore, the SiH compounds remain in the gate insulating layer even after the MOSFET is manufactured. If the SiH compounds remain, there is a high possibility that hydrogen atoms are released from the SiH compounds in the gate insulating layer during the operation of the MOSFET and the dangling bonds of the silicon atoms are formed again as described above.

As illustrated in FIG. 10, the interstitial hydrogen forms the trap state in the energy band of silicon dioxide. Therefore, if the interstitial hydrogen remains in the gate insulating layer 28 after the third heat treatment performed in the atmosphere containing the hydrogen gas (H₂), for example, charge is trapped in the trap state, so that the decrease in the carrier mobility, the fluctuation in the threshold voltage, or the increase in the leakage current of the gate insulating layer occurs. Therefore, it is desirable to reduce an amount of the interstitial hydrogen in the gate insulating layer.

In the method for manufacturing the semiconductor device of the first embodiment, the fourth heat treatment is performed in the atmosphere in which the partial pressure of the hydrogen gas is lower than the partial pressure of the hydrogen gas in the atmosphere of the third heat treatment. By the fourth heat treatment, the interstitial hydrogen in the gate insulating layer 28 diffuses outward, and the interstitial hydrogen in the gate insulating layer 28 decreases.

From the viewpoint of promoting the outward diffusion of the interstitial hydrogen in the gate insulating layer 28, the partial pressure of the hydrogen gas in the fourth heat treatment is preferably less than 5%. From the viewpoint of promoting the outward diffusion of the interstitial hydrogen in the gate insulating layer 28, the fourth heat treatment is preferably performed in a nitrogen gas atmosphere or an argon gas atmosphere.

The temperature of the fourth heat treatment is preferably equal to or lower than the temperature of the second heat treatment and equal to or lower than the temperature of the third heat treatment from the viewpoint of suppressing the increase in the oxygen vacancies in the gate insulating layer 28.

Note that the fourth heat treatment can also be omitted, for example, when the amount of the interstitial hydrogen in the gate insulating layer 28 after the third heat treatment is small.

By the method for manufacturing the semiconductor device of the first embodiment, it is possible to reduce the harmful defects that cause the decrease in the carrier mobility of the MOSFET in the gate insulating layer 28 or the fluctuation in the threshold voltage, that is, reduce the oxygen vacancies, the CON compounds, and interstitial hydrogen. Therefore, the amount of the harmful defects in the gate insulating layer 28 of the MOSFET 100 can be reduced, and the decrease in the carrier mobility or the fluctuation in the threshold voltage can be suppressed.

In the MOSFET 100 of the first embodiment, the gate insulating layer 28 is a silicon oxide layer containing carbon (C), nitrogen (N), and hydrogen (H).

In the MOSFET 100 of the first embodiment, as illustrated in FIG. 3, the first concentration (C1 in FIG. 3) of nitrogen at the first position 10 nm away from the peak of the nitrogen concentration distribution toward the gate insulating layer 28 is 1×10¹⁸ cm⁻³ or more and 1×10²¹ cm⁻³ or less. In addition, a second concentration (C2 in FIG. 3) of carbon at the first position is 1×10¹⁸ cm⁻³ or more and 1×10²¹ cm⁻³ or less. In addition, a third concentration (C3 in FIG. 3) of hydrogen at the first position is 1×10¹⁸ cm⁻³ or more and 1×10²¹ cm⁻³ or less.

The second concentration C2 is 80% or more and 120% or less of the first concentration C1. In addition, the third concentration C3 is 80% or more and 120% or less of the first concentration C1.

In addition, as illustrated in FIG. 3, for example, the fourth concentration (C4 in FIG. 3) of nitrogen at the second position 20 nm away from the peak of the nitrogen concentration distribution toward the gate insulating layer 28 is 1×10¹⁸ cm⁻³ or more and 1×10²¹ cm⁻³ or less. In addition, for example, a fifth concentration (C5 in FIG. 3) of carbon at the second position is 1×10¹⁸ cm⁻³ or more and 1×10²¹ cm⁻³ or less. In addition, for example, a sixth concentration (C6 in FIG. 3) of hydrogen at the second position is 1×10¹⁸ cm⁻³ or more and 1×10²¹ cm⁻³ or less.

Then, for example, the fifth concentration C5 is 80% or more and 120% or less of the fourth concentration C4. In addition, for example, the sixth concentration C6 is 80% or more and 120% or less of the fourth concentration C4.

In addition, as illustrated in FIG. 3, for example, the seventh concentration (C7 in FIG. 3) of nitrogen at the third position 30 nm away from the peak of the nitrogen concentration distribution toward the gate insulating layer 28 is less than 1×10¹⁸ cm⁻³. In addition, for example, an eighth concentration (C8 in FIG. 3) of carbon at the third position is less than 1×10¹⁸ cm⁻³. In addition, a ninth concentration (C9 in FIG. 3) of hydrogen at the third position is less than 1×10¹⁸ cm⁻³.

For example, the eighth concentration C8 is 80% or more and 120% or less of the seventh concentration C7. In addition, for example, the ninth concentration C9 is 80% or more and 120% or less of the seventh concentration C7.

In the MOSFET 100 of the first embodiment, most of carbon atoms, nitrogen atoms, and hydrogen atoms contained in the gate insulating layer 28 are fixed as the CONH compounds. Therefore, as illustrated in FIG. 3, the distribution of the carbon atoms, the distribution of the nitrogen atoms, and the distribution of the hydrogen atoms overlap in the gate insulating layer 28.

Carbon in the gate insulating layer 28 is carbon released from the surface of the silicon carbide layer 10 and diffused by the first heat treatment. Therefore, for example, as illustrated in FIG. 3, the carbon concentration decreases in the gate insulating layer 28 as the distance from the silicon carbide layer 10 increases.

In the MOSFET 100 of the first embodiment, most of carbon atoms, nitrogen atoms, and hydrogen atoms contained in the gate insulating layer 28 are fixed as the CONH compounds which are defects harmless to the characteristics of the MOSFET 100. In other words, the amount of the oxygen vacancies, CON bonds, and the interstitial hydrogen, which are defects harmful to the characteristics of the MOSFET 100, is extremely small in the gate insulating layer 28 of the MOSFET 100. In the MOSFET 100, since the amount of the harmful defects in the gate insulating layer 28 is reduced, the decrease in the carrier mobility or the fluctuation in the threshold voltage can be suppressed.

As described above, according to the first embodiment, the semiconductor device and the method for manufacturing the semiconductor device in which the amount of the harmful defects in the gate insulating layer is reduced are realized.

### Second Embodiment

A semiconductor device of a second embodiment is different from that of the first embodiment in terms of being a MOSFET of a trench gate type including a gate electrode in a trench. In addition, a difference from the first embodiment is that a surface of a silicon carbide layer facing the gate electrode is a face inclined at 0° or more and 8° or less with respect to a {1-100} face or a face inclined at 0° or more and 8° or less with respect to a {11-20} face. Hereinafter, some of the content overlapping with that in the first embodiment will not be described.

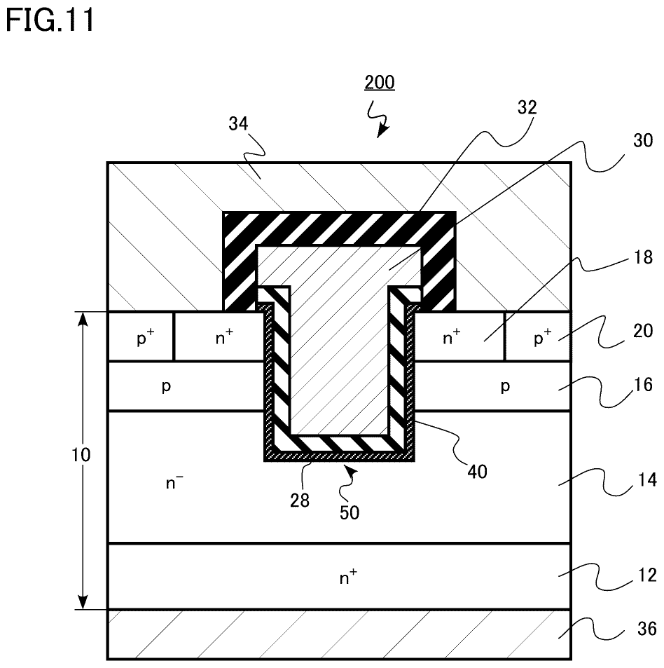

FIG. 11 is a schematic cross-sectional view of the semiconductor device of the second embodiment. The semiconductor device of the second embodiment is a MOSFET 200. The MOSFET 200 is the MOSFET of the trench gate type including the gate electrode in the trench. In addition, the MOSFET 200 is an n-channel MOSFET using electrons as carriers.

The MOSFET 200 includes the silicon carbide layer 10, the gate insulating layer 28 (silicon oxide layer), the gate electrode 30, the interlayer insulating film 32, the source electrode 34, the drain electrode 36, the interface termination region 40 (region), and a trench 50.

The silicon carbide layer 10 includes the drain region 12, the drift region 14, the p-well region 16, the source region 18, and the p-well contact region 20.

The trench 50 penetrates the source region 18 and the p-well region 16 and reaches the drift region 14. A bottom face of the trench 50 is disposed in the drift region 14.

The gate insulating layer 28 and the gate electrode 30 are provided in the trench 50. A side face of the trench 50 is, for example, a face having an off-angle of 0° or more and 8° or less with respect to an m-face, or a face having an off-angle of 0° or more and 8° or less with respect to an a-face.

On the side face of the trench 50, a surface of the silicon carbide layer 10 facing the gate electrode 30 is, for example, a face inclined at 0° or more and 8° or less with respect to the {1-100} face, or a face inclined at 0° or more and 8° or less with respect to the {11-20} face.

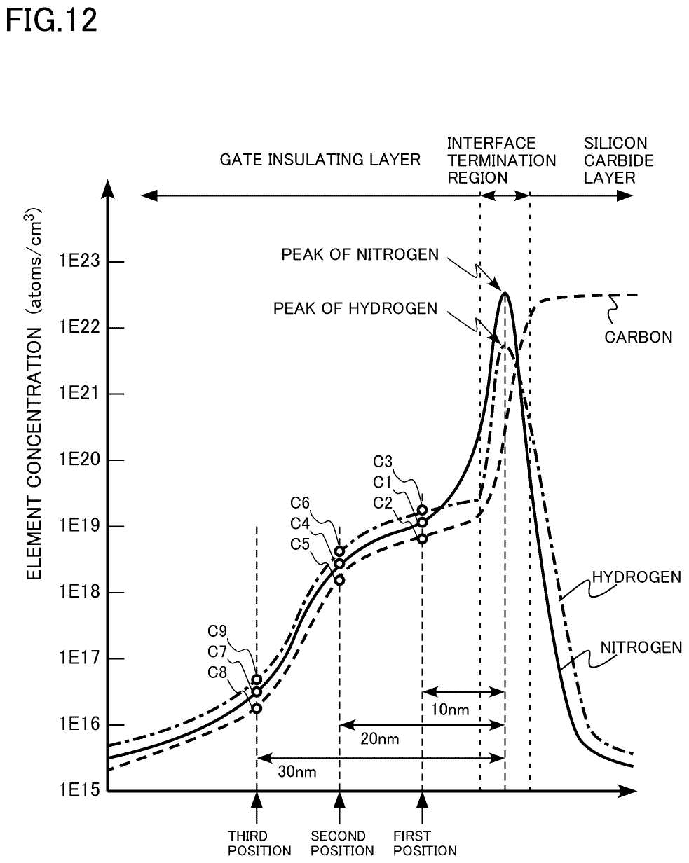

FIG. 12 is a graph illustrating element concentration distributions of the semiconductor device of the second embodiment. FIG. 12 is a graph illustrating the element concentration distributions in the gate insulating layer 28, the interface termination region 40, and the silicon carbide layer 10 on the side face of the trench 50.

FIG. 12 illustrates concentration distributions of nitrogen (N), carbon (C), and hydrogen (H). In FIG. 12, a solid line indicates the nitrogen concentration distribution, a dotted line indicates the carbon concentration distribution, and an alternate long and short dash line indicates the hydrogen concentration distribution.

The nitrogen concentration distribution has a peak in the interface termination region 40. The nitrogen concentration at the peak is, for example, 1×10²¹ cm⁻³ or more and 4×10²³ cm⁻³ or less. A full width at half maximum for the peak of the nitrogen concentration distribution is, for example, 1 nm or less. Nitrogen is segregated at an interface between the silicon carbide layer 10 and the gate insulating layer 28.

The hydrogen concentration distribution has a peak in the interface termination region 40. The hydrogen concentration at the peak is, for example, 1×10²¹ cm⁻³ or more and 1×10²³ cm⁻³ or less. A full width at half maximum for the peak of the hydrogen concentration distribution is, for example, 1 nm or less. Hydrogen is segregated at the interface between the silicon carbide layer 10 and the gate insulating layer 28. A hydrogen atom present in the interface termination region 40 is bonded to a carbon atom.

According to the MOSFET 200 of the second embodiment, an amount of harmful defects in the gate insulating layer 28 is reduced, and a decrease in carrier mobility or a fluctuation in a threshold voltage can be suppressed as in the MOSFET 100 of the first embodiment.

When a MOSFET having a trench gate structure is formed using silicon carbide, there is a problem that the threshold voltage fluctuates due to AC stress. One factor is considered to be an interface state between the silicon carbide layer and the gate insulating layer. The interface state is considered to be generated particularly by dangling bonds of carbon present on an inner face of the trench. It is considered that, when the AC stress is applied, charge injected into the interface between the silicon carbide layer and the gate insulating layer is trapped in the interface state, and the threshold voltage fluctuates.

For example, when the inner face of the trench is the m-face or the a-face, the dangling bonds of carbon atoms are present on the outermost surface unlike a Si face.

In the method for manufacturing the MOSFET 200 of the second embodiment, a third heat treatment performed in an atmosphere containing hydrogen gas (H₂) is performed. As the third heat treatment is performed, the dangling bonds of the carbon atoms are terminated by hydrogen atoms. In the MOSFET 200 of the second embodiment, since the dangling bonds of the carbon atoms are terminated by the hydrogen atoms, the hydrogen concentration distribution has the peak in the interface termination region 40. In the MOSFET 200, the dangling bonds of the carbon atoms on the surface of the silicon carbide layer are reduced, and the fluctuation in the threshold voltage due to the AC stress of the MOSFET 200 can be suppressed.

As described above, according to the second embodiment, the semiconductor device and the method for manufacturing the semiconductor device in which the amount of the harmful defects in the gate insulating layer is reduced are realized.

### Third Embodiment

An inverter circuit and a driving device of a third embodiment correspond to an inverter circuit and a driving device that includes the semiconductor device of the first embodiment.

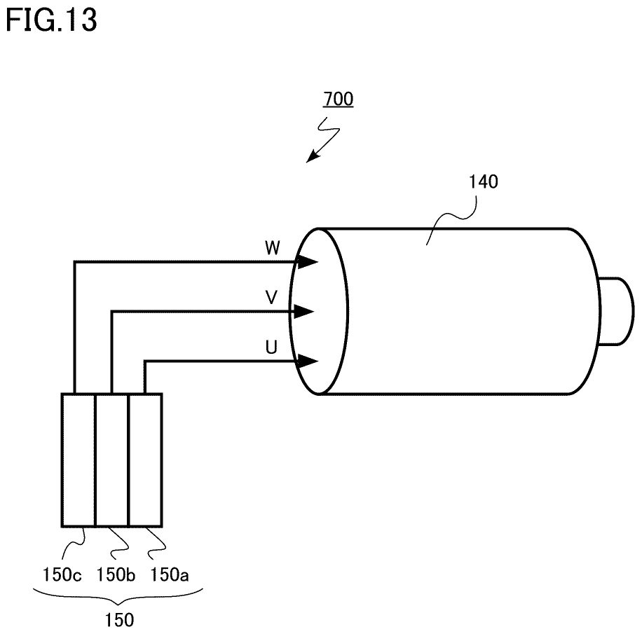

FIG. 13 is a schematic view of the driving device of the third embodiment. A driving device 700 includes a motor 140 and an inverter circuit 150.

The inverter circuit 150 includes three semiconductor modules 150a, 150b, and 150c using the MOSFET 100 of the first embodiment as a switching element. The three-phase inverter circuit 150 having three AC voltage output terminals U, V, and W is realized by connecting the three semiconductor modules 150a, 150b, and 150c in parallel. The motor 140 is driven by the AC voltage output from the inverter circuit 150.

According to the third embodiment, characteristics of the inverter circuit 150 and the driving device 700 are improved by providing the MOSFET 100 with improved characteristics.

### Fourth Embodiment

A vehicle of a fourth embodiment is a vehicle including the semiconductor device of the first embodiment.

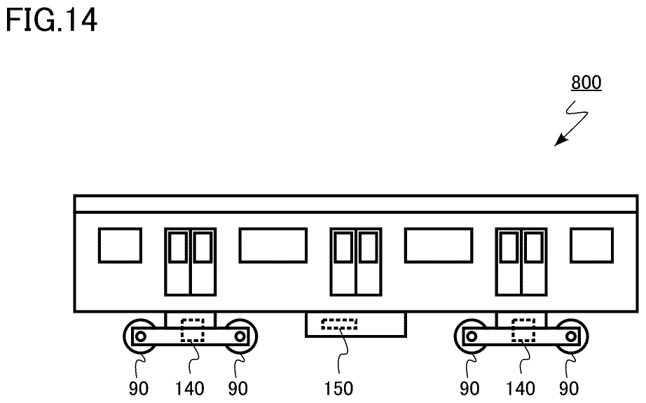

FIG. 14 is a schematic view of the vehicle of the fourth embodiment. A vehicle 800 of the fourth embodiment is a railway vehicle. The vehicle 800 includes the motor 140 and the inverter circuit 150.

The inverter circuit 150 includes three semiconductor modules using the MOSFET 100 of the first embodiment as a switching element. The three-phase inverter circuit 150 having three AC voltage output terminals U, V, and W is realized by connecting the three semiconductor modules in parallel. The motor 140 is driven by the AC voltage output from the inverter circuit 150. Wheels 90 of the vehicle 800 are rotated by the motor 140.

According to the fourth embodiment, characteristics of the vehicle 800 are improved by providing the MOSFET 100 with improved characteristics.

### Fifth Embodiment

A vehicle of a fifth embodiment is a vehicle including the semiconductor device of the first embodiment.

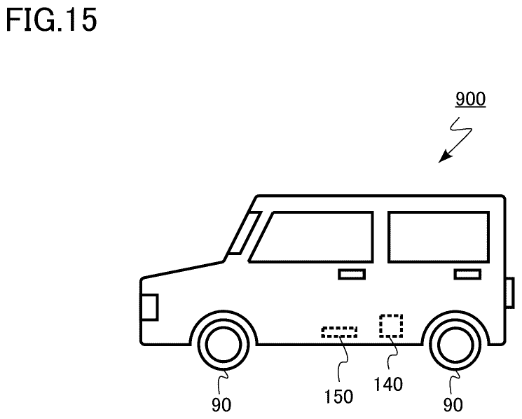

FIG. 15 is a schematic view of the vehicle of the fifth embodiment. A vehicle 900 of the fifth embodiment is a car. The vehicle 900 includes the motor 140 and the inverter circuit 150.

The inverter circuit 150 includes three semiconductor modules using the MOSFET 100 of the first embodiment as a switching element. The three-phase inverter circuit 150 having three AC voltage output terminals U, V, and W is realized by connecting the three semiconductor modules in parallel.

The motor 140 is driven by the AC voltage output from the inverter circuit 150. Wheels 90 of the vehicle 900 are rotated by the motor 140.

According to the fifth embodiment, characteristics of the vehicle 900 are improved by providing the MOSFET 100 with improved characteristics.

### Sixth Embodiment

An elevator of a sixth embodiment is an elevator including the semiconductor device of the first embodiment.

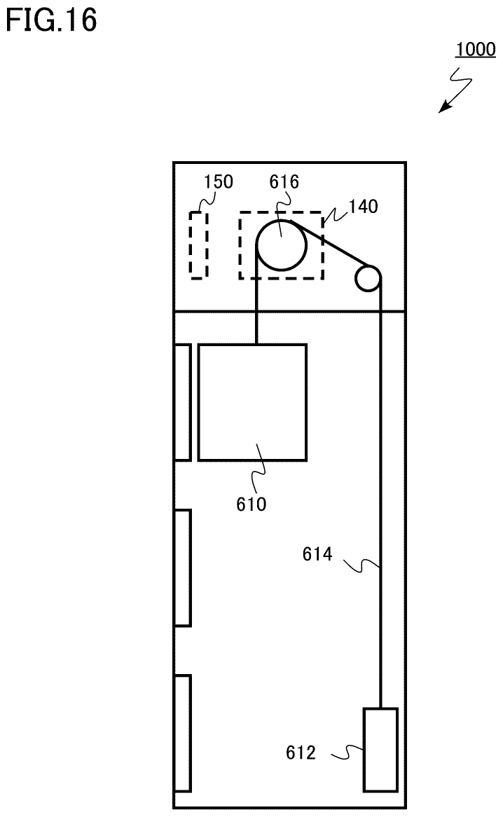

FIG. 16 is a schematic view of the elevator of the sixth embodiment. An elevator 1000 of the sixth embodiment includes an elevator car 610, a counterweight 612, a wire rope 614, a hoisting machine 616, the motor 140, and the inverter circuit 150.

The inverter circuit 150 includes three semiconductor modules using the MOSFET 100 of the first embodiment as a switching element. The three-phase inverter circuit 150 having three AC voltage output terminals U, V, and W is realized by connecting the three semiconductor modules in parallel.

The motor 140 is driven by the AC voltage output from the inverter circuit 150. The hoisting machine 616 is rotated by the motor 140 to move the elevator car 610 up and down.

According to the sixth embodiment, characteristics of the elevator 1000 are improved by providing the MOSFET 100 with improved characteristics.

As described above, the description has been given in the first or second embodiment by exemplifying the case of 4H—SiC as the crystal structure of silicon carbide, but the present disclosure can also be applied to silicon carbide having other crystal structures such as 6H—SiC and 3C—SiC.

An oxidation rate of the silicon carbide layer has plane-orientation dependence. In the first or second embodiment, it is preferable to optimize the temperature of the first heat treatment according to the plane orientation.

In addition, the present invention can also be applied to an n-channel insulated gate bipolar transistor (IGBT).

In addition, the present invention can be applied not only to the n-channel type but also to a MOSFET or an IGBT of a p-channel type.

In addition, the description has been given in the third to sixth embodiments by exemplifying the case where the semiconductor device of the present disclosure is applied to a vehicle or an elevator has been described as an example, but the semiconductor device of the present disclosure can also be applied to, for example, a power conditioner of a photovoltaic power generation system or the like.

Although the case where the semiconductor device of the first embodiment is applied has been described as an example in the third to sixth embodiments, the semiconductor device of the second embodiment can also be applied, for example.

While certain embodiments have been described, these embodiments have been presented by way of example only, and are not intended to limit the scope of the inventions. Indeed, the semiconductor device, the method for manufacturing the semiconductor device, the inverter circuit, the driving device, the vehicle, and the elevator described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a silicon carbide layer;
a gate electrode;
a silicon oxide layer provided between the silicon carbide layer and the gate electrode, the silicon oxide layer containing carbon (C), nitrogen (N), and hydrogen (H); and
a region provided between the silicon carbide layer and the silicon oxide layer, the region having a nitrogen concentration equal to or more than 1×10²¹ cm⁻³,
wherein a nitrogen concentration distribution in the silicon carbide layer, the silicon oxide layer, and the region has a peak in the region,
a first concentration of nitrogen at a first position 10 nm away from the peak toward the silicon oxide layer is equal to or more than 1×10¹⁸ cm⁻³,
a second concentration of carbon at the first position is equal to or more than 1×10¹⁸ cm⁻³,
a third concentration of hydrogen at the first position is equal to or more than 1×10¹⁸ cm⁻³,
the second concentration is 80% or more and 120% or less of the first concentration, and
the third concentration is 80% or more and 120% or less of the first concentration.

2. The semiconductor device according to claim 1, wherein hydrogen atoms are bonded to nitrogen atoms in the silicon oxide layer.

3. The semiconductor device according to claim 1, wherein an amount of hydrogen atoms bonded to nitrogen atoms in the silicon oxide layer is larger than an amount of hydrogen atoms bonded to silicon atoms.

4. The semiconductor device according to claim 1, wherein
the first concentration is equal to or more than 1×10¹⁹ cm⁻³,
the second concentration is equal to or more than 1×10¹⁹ cm⁻³, and
the third concentration is equal to or more than 1×10¹⁹ cm⁻³.

5. The semiconductor device according to claim 1, wherein
a fourth concentration of nitrogen at a second position 20 nm away from the peak toward the silicon oxide layer is equal to or more than 1×10¹⁸ cm⁻³,
a fifth concentration of carbon at the second position is equal to or more than 1×10¹⁸ cm⁻³,
a sixth concentration of hydrogen at the second position is equal to or more than 1×10¹⁸ cm⁻³,
the fifth concentration is 80% or more and 120% or less of the fourth concentration, and
the sixth concentration is 80% or more and 120% or less of the fourth concentration.

6. The semiconductor device according to claim 1, wherein
a seventh concentration of nitrogen at a third position 30 nm away from the peak toward the silicon oxide layer is less than 1×10¹⁸ cm⁻³,
an eighth concentration of carbon at the third position is less than 1×10¹⁸ cm⁻³, and
a ninth concentration of hydrogen at the third position is less than 1×10¹⁸ cm⁻³.

7. The semiconductor device according to claim 1, wherein a surface of the silicon carbide layer facing the gate electrode is a face inclined at 0° or more and 8° or less with respect to a {1-100} face or a face inclined at 0° or more and 8° or less with respect to a {11-20} face.

8. The semiconductor device according to claim 7, wherein a concentration of hydrogen in the region is equal to or more than 1×10²¹ cm⁻³.

9. An inverter circuit comprising the semiconductor device according to claim 1.

10. A driving device comprising the semiconductor device according to claim 1.

11. A vehicle comprising the semiconductor device according to claim 1.

12. An elevator comprising the semiconductor device according to claim 1.

13. A method for manufacturing a semiconductor device, the method comprising:
forming a silicon oxide film on a surface of a silicon carbide layer;
performing a first heat treatment at a temperature of 1100° C. or higher and 1300° C. or lower in an atmosphere containing nitrogen oxide gas after the forming the silicon oxide film;
performing a second heat treatment at a temperature of 100° C. or higher and 600° C. or lower in an atmosphere containing oxygen gas after the performing the first heat treatment;
performing a third heat treatment at a temperature of 100° C. or higher and 600° C. or lower in an atmosphere containing hydrogen gas after the performing the second heat treatment; and
forming a gate electrode on the silicon oxide film after the performing the third heat treatment.

14. The method for manufacturing a semiconductor device according to claim 13, wherein an atmosphere of the third heat treatment contains nitrogen gas.

15. The method for manufacturing a semiconductor device according to claim 13, wherein a temperature of the third heat treatment is equal to or lower than the temperature of the second heat treatment.

16. The method for manufacturing a semiconductor device according to claim 13, further comprising performing, after the performing the third heat treatment and before the forming the gate electrode, a fourth heat treatment at a temperature of 100° C. or higher and 600° C. or lower in an atmosphere with a lower partial pressure of hydrogen gas than an atmosphere of the third heat treatment.

17. The method for manufacturing a semiconductor device according to claim 16, wherein the temperature of the fourth heat treatment is equal to or lower than a temperature of the third heat treatment.

18. The method for manufacturing a semiconductor device according to claim 13, wherein the silicon oxide film is formed by vapor phase growth.

19. The method for manufacturing a semiconductor device according to claim 13, wherein the silicon oxide film has a thickness of 30 nm or more and 100 nm or less.

20. The method for manufacturing a semiconductor device according to claim 13, wherein the surface is a face inclined at 0° or more and 8° or less with respect to a {1-100} face or a face inclined at 0° or more and 8° or less with respect to a {11-20} face.
